(19) United States
(12) Patent Application Publication
(10) Pub. No.: US 2019/0096630 A1
(43) Pub. Date: Mar. 28, 2019

(54) DEVICE AND METHOD FOR GENERATING CHARGED PARTICLE BEAM PULSES

(71) Applicant: TECHNISCHE UNIVERSITEIT DELFT, Delft (NL)

(72) Inventors: Pieter KRUIT, Delft (NL); Izaak Gerrit Cornelis WEPPELMAN, Delft (NL)

(21) Appl. No.: 15/526,995

(22) PCT Filed: Nov. 11, 2015
(86) PCT No.: PCT/NL2015/050789

§ 371 Date: May 15, 2017

(30) Foreign Application Priority Data
Nov. 14, 2014 (NL) 2013801

(51) Int. Cl. H01J 37/244; H01J 37/147; H01J 37/22; H01J 37/04; H01J 37/28

(52) U.S. Cl. CPC H01J 37/244; H01J 37/1474; H01J 37/226; H01J 37/21; H01J 37/22; H01J 37/28; H01J 2237/043; H01J 37/045

(57) ABSTRACT

Disclosed is a device for, in combination with a stop having an aperture, generating charged particle beam pulses, an apparatus for inspecting a surface of a sample, and a method for inspecting a surface of a sample. The device includes a deflection unit which is arranged for positioning in or along a trajectory of a charged particle beam. The deflection unit is arranged for generating an electric field for deflecting said charged particle beam over the stop and across the aperture. The device also includes an electrical driving circuit for providing a periodic signal. The electrical driving circuit is connected to the manipulation unit via a photoconductive switch, wherein the photoconductive switch is arranged for: substantially insulating the deflection unit from the electrical driving circuit, and for conductively connecting the deflection unit to the electrical driving circuit only when said photoconductive switch is illuminated by a light beam.

### BACKGROUND

The invention relates to a beam deflecting device, fast enough to be used for Ultrafast Electron Microscopy (UEM). Lately there is a demand in studying time dependent effects with time resolutions in the picosecond and femtosecond range, in an electron microscope.

A charged particle imaging apparatus, like an electron microscope, is capable to image the constituents of a sample at very small detail (high resolution), higher than can be achieved with a light microscope, but the capability to also follow processes at femtosecond and picosecond time scales is absent, in general. For UEM it is necessary to create a pulsed electron beam, where the pulse length will set the temporal resolution of the UEM.

The U.S. Pat. No. 8,569,712 for example, discloses an electrostatic beam deflector for a particle-optical apparatus, in which a diaphragm comprising an aperture is used for interrupting a beam of charged particles. The beam deflector is used to sweep the beam of charged particles over the diaphragm and across the aperture to generate a train of pulses with a fixed repetition rate, such pulse trains with a sub-picosecond pulse length are for example used in the study of chemistry in the femtosecond scale.

The beam blanker disclosed in U.S. Pat. No. 8,569,712 has an axis along which the beam of charged particles propagate. The beam blanker comprises two deflector electrodes for generating an electric field perpendicular to said axis, wherein said electric field is arranged for deflecting the charged particles. In addition the blanker comprises a diaphragm with an aperture, wherein the aperture is arranged to transmit the beam of charged particles when the beam is not deflected and the diaphragm is arranged to block the beam of charged particles when is deflected by the electric field. The electric field is generated by a resonant structure with a resonant frequency f, which resonant structure is arranged to generate an electric field that sweeps the beam of charged particles over the aperture. As a result, the charged particle beam is transmitted through the aperture twice per period of the frequency f.

U.S. Pat. No. 8,569,712 describes a design of an electrostatic beam blanker comprising a resonant circuit working at a resonant frequency in excess of 1 GHz, more specifically in excess of 10 GHz, resulting in a bunch length of 1 pico-second (ps) or less.

Preferably the charged particle imaging apparatus is provided with a laser, such as a nano-, pico- or femto-second laser, producing a train of light pulses for probing the sample. When synchronizing the laser and the beam blanker, time dependent studies on ultra-short (femto-second) timescale or longer can be performed.

One of the problems of the prior art electrostatic beam blanker is the synchronization of a femtosecond laser, typically with repetition rates of 100 MHz, jitter free to a beam blanker working with GHz electrical signals. As described in U.S. Pat. No. 8,569,712, the electrical resonant circuit generating these signals can be locked to the pulsed laser system using a photoreceptor in the electrical circuit to synchronize the GHz signal from the electrical circuit. However, still there will be some jitter left by locking an electrical circuit to a pulsed laser system.

Another disadvantage is the order of magnitude higher repetition rate of the electron pulses with respect to the optical pulses, which is unavoidable in such a design because the resonant circuit usually depends on high Q factor resonances to build up strong enough deflection fields.

It is an object of the present invention to provide an ultrafast beam deflector, such as a beam blanker, for use in electron microscopes which at least partially solves one or more of the above identified problems.

### SUMMARY OF THE INVENTION

According to a first aspect, the invention relates to a device for, in combination with a stop comprising an aperture or slit, generating charged particle beam pulses, wherein the device comprises a manipulation unit which is arranged for positioning in or along a trajectory of a charged particle beam, and wherein the manipulation unit is arranged for generating an electric field for deflecting said charged particle beam over said stop and across the aperture or slit, wherein the device comprises an electrical driving circuit for providing a voltage to the deflection unit, wherein the electrical driving circuit is electrically connected to the deflection unit via a photoconductive switch, wherein the photoconductive switch is arranged for:

conductively connecting the deflection unit to the electrical driving circuit when said photoconductive switch is illuminated by a light beam of an intensity larger than a predetermined intensity value, for transmitting the voltage of the electrical driving circuit to the deflection unit, and

substantially insulating the deflection unit from the electrical driving circuit when the photoconductive switch is not illuminated by a light beam, wherein the voltage over the photoconductive switch can be changed without affecting the voltage on the deflection electrode when the photoconductive switch is substantially insulating.

According to the present invention, the photoconductive switch is arranged between the deflection unit and the electrical driving circuit. Preferably, the electrical driving circuit, the photoconductive switch and the deflection unit are electrically connected in series. It was found that photoconductive switches are capable of generating electric signals with bandwidths in the tera-Hertz range.

When the photoconductive switch is not illuminated by a light beam, the photoconductive switch is in a substantially non-conducting or insulating state, and the deflection unit is isolated or cut off from the electrical driving circuit. That is, changes in the voltage provided by the electrical driving circuit are substantially not transmitted to the deflection unit.

When the photoconductive switch is illuminated by a light beam, the photoconductive switch transfers into a conducting state, and the deflection unit is conductively connected to the electrical driving circuit. That is, the voltage of the electrical driving circuit is transmitted to the deflection unit. In particular, when the photoconductive switch is illuminated by the light beam, the resistance of the photoconductor in its conductive state can be set by the amount of photons in a light or laser pulse, causing a decrease in the rise time of the transmission of the voltage from the electric driving circuit to the deflection unit. The deflection unit according to the invention can suitably be used for ultrafast electron microscopy because it can provide an electrostatic field with a fast rise time. Accordingly, the deflection unit of the invention can provide a high slew rate, for example a dV/dt of approximately 10¹⁴ V/s, in order to generate ultra short electron pulses when used as deflection unit in combination with a stop with an aperture as described in more detail below.

In addition, the voltage on the deflection unit is not affected when the photoconductive switch is substantially insulating. Thus, after the photoconductive switch is illuminated by the light beam, the voltage of the electrical driving circuit is transmitted to the deflection unit, the illumination of the photoconductive switch is stopped and the photoconductive switch returns to the substantially insulating state, the voltage on the deflection unit substantially does not change and is substantially held at the voltage of the electrical driving circuit which was transmitted to the deflection unit during the illumination of the photoconductive switch. The voltage on the deflection unit is substantially unaffected and constant until the photoconductive switch is illuminated again. Because the voltage on the deflection unit between successive illuminations remains substantially constant, the charged particle beam substantially remains at the same position, at particular at the same side next to the aperture or slit of the stop. This feature prevents that the charged particle beam sweeps over said stop and across the aperture or slit when the photoconductive switch is not illuminated. A next deflection of the charged particle beam to sweep over the stop and across the aperture or slit will occur when the voltage of the electrical driving circuit has changed and the photoconductive switch is illuminated to transmit the changed voltage of the driving circuit to the deflection unit.

Thus, the device according to the first aspect of the invention utilizes a ‘sample and hold’ scheme, and is arranged such that the deflection unit

samples the voltage of the electrical driving circuit via the photoconductive switch when the photoconductive switch is illuminated by a light beam, and

holds the sampled voltage when the light beam is switched off and photoconductive switch is not illuminated, at least until the photoconductive switch is subsequently illuminated by the light beam.

In addition, in order to generate a short charged particle pulses, the device of the present invention is arranged to deflect the charged particle beam across the aperture or slit; from one side of the aperture or slit to the other side of said aperture or slit. The charged particle pulse is generated during the crossing or transition of the charged particle beam over the aperture or slit. This aspect is not used in beam blankers as used in lithography systems as for example disclosed in US2010/0045958. Beam deflectors used in lithography system, and particular the one described in US2010/0045958, are arranged to be turned on or off. When the deflector is turned on, an electric field is established across the aperture, which results in a deflection of the charged particle beam and the deflected charged particle beam is stopped by the beam stop array, as shown in FIG. 10 of US2010/0045958. When the deflector is turned off, the charged particle beam is not deflected and is transmitted towards a target. So the beam blanker for a lithography system as disclosed in US2010/0045958 is not arranged for deflecting the charged particle beam from one side to the other side across the aperture in the beam stop array.

In an embodiment, the electrical driving circuit is arranged for generating an alternating voltage, and for applying said alternating voltage on the photoconductive switch. The voltage applied on the metal electrode of the photoconductive switch which is connected to the electrical driving circuit is inverted preferably each time between two consecutive light pulses, in particular from a pulsed laser, when the photoconductive switch is in a state of high resistance or in the non-conducting state. Each time that the photoconductive switch is illuminated by the light or laser beam, the deflection unit is connected to the inverted voltage of the electrical driving circuit and inverses the voltage over the deflection unit, and the charged particle beam makes a sweep each time the voltage over the deflector unit is inverted. In an embodiment, the electrical driving circuit is arranged for synchronizing the alternating voltage to a repetition rate of a pulsed laser system which is used for illuminating the photoconductive switch, preferably wherein the alternating voltage is modulated with half the repetition rate of the pulsed laser system. In an embodiment, the alternating voltage is modulated with 1/(2n) times the repetition rate of a pulsed laser system which is used for illuminating the photoconductive switch, wherein n is an integer value larger than 0.

According to a second aspect, the invention relates to a device for, in combination with a stop comprising an aperture or slit, generating charged particle beam pulses, wherein the device comprises a manipulation unit which is arranged for positioning in or along a trajectory of a charged particle beam, and wherein the manipulation unit is arranged for generating an electric field for deflecting said charged particle beam over said stop and across the aperture or slit, wherein the device comprises an electrical driving circuit for providing a voltage to the deflection unit, wherein the electrical driving circuit is electrically connected to the deflection unit via a photoconductive switch, wherein the photoconductive switch is arranged for:

substantially insulating the deflection unit from the electrical driving circuit, and for

conductively connecting the deflection unit to the electrical driving circuit when said photoconductive switch is illuminated by a light beam of an intensity larger than a predetermined intensity value, wherein the deflection unit, in particular a first electrode thereof, is also connected to the electrical driving circuit or to ground potential via a resistor, wherein the resistor has a resistance substantially higher than the resistance of the photoconductive switch when said photoconductive switch is illuminated by a light beam.

The defection unit will provide a fast sweep of the charged particle beam in case the light or laser pulse illuminates the switch. However, when the photoconductor goes back to its dark state, the charged particle beam will make a second slow sweep in a direction opposite to the fast sweep. In case such a second slow sweep and thus a second longer charged particle beam pulse would be undesirable, a pulse picker described below can be used to deflect the charged particle beam so that its sweeping path no longer extends from one side to the other side across the aperture to prevent a second slow charged particle beam pulse of said second sweep to reach the sample. Thus, the device according to the second aspect of the invention is arranged such that the deflection unit

samples the voltage of the electrical driving circuit via the photoconductive switch when the photoconductive switch is illuminated by a light beam, and

discharges the voltage over the deflection unit via the resistor when the light beam is switched off and photoconductive switch is not illuminated.

In an embodiment, the driving circuit comprises a power supply, wherein said power supply, said photoconductive switch and said resistor are arranged in series to provide an electric circuit, and wherein the deflection unit is connected to the electrical driving circuit in between said photoconductive switch and said resistor. Due to the discharging of the deflection unit in-between successive illuminations of the photoconductive switch, the power supply is preferably arranged to provide a substantially constant voltage.

The features of following embodiments as described below can be applied in the device according to the first aspect and also in the device according to the second aspect.

In an embodiment, the photoconductive switch comprises a piece of semi-insulating semiconductor material between two metal electrodes forming an Ohmic contact. Such a photoconductive switch is preferably illuminated by a light pulse or laser pulse. When illuminated by a light pulse or laser pulse, the light creates electron-hole pairs in the semiconductor and a current can flow between the two metal electrodes. After a short while after the illumination by the light pulse, the conductivity vanishes due to recombination of the electron hole pairs.

According to an embodiment, the deflection unit comprises a first electrode and a second electrode, which are arranged at a distance from each other, and wherein at least one of said first and second electrode is connected to the electrical driving circuit. A voltage difference between the first and the second electrode provides an electrostatic field in between the electrodes which is used for deflecting the charged particle beam.

In an embodiment, the photoconductive switch is directly connected to the first electrode. Preferably, the photoconductive switch is arranged directly adjacent to the first electrode. In case the photoconductive switch and the deflection unit are located far apart from each other, the bandwidth of the beam deflection signal over the deflection unit will be limited due to absorption, and the rise time will also be limited by dispersion or by the RC time.

In an embodiment, the deflection unit and the photoconductive switch are arranged and/or integrated on one single chip. The integration of the photoconductive switch and the deflection unit assist to obtain short switching times.

In an embodiment, the electrodes are arranged at substantially opposite sides of the trajectory of the charged particle beam. The electrodes are arranged in order to provide a passage for the charged particle beam between the first and second electrode. In use, the deflection unit is arranged with respect to the trajectory of the charged particle beam to pass in between the first and the second electrode. The deflection unit according to this embodiment is arranged to provide an electrostatic field which in use is directed substantially perpendicular to a trajectory of the charged particle beam for deflecting the charged particle beam.

In an embodiment, the deflection unit is a first deflection unit, and wherein the device comprises a second deflection unit or deflector which is arranged for positioning in or along a trajectory of a charged particle beam, and wherein the second deflector is arranged for generating a second electric field in a direction substantially perpendicular to the electric field of the first deflection unit. The second deflector can be used as a pulse picker; it can prevent that some or all of the charged particle beam pulses provided by the sweeping of the charged particle beam over the stop and across the aperture or slit by the deflection unit, reaches the sample.

In a further embodiment, the photoconductive switch is a first photoconductive switch, wherein the electrical driving circuit comprises a first power supply which is connected to the deflection unit via the first photoconductive switch, and wherein the electrical driving circuit comprises a second power supply which is connected to the deflection unit via a second photoconductive switch. In an embodiment, the first and second photoconductive switches are arranged for alternate illumination by the light beam. When the light beam illuminates the first photoconductive switch, the deflector unit is connected to the first power supply and a deflector electrode is charged to the voltage delivered by this first power supply. When a subsequent light beam illuminates the second photoconductive switch, the deflector unit is connected to the second power supply and the deflector electrode is charged to the voltage delivered by this second power supply. In this way the voltage on the deflector electrode can make a sweep in picosecond or femtosecond timescale from the voltage delivered by the first power supply to the voltage of the second power supply, or the other way around. In an embodiment, a resistance of the first photoconductive switch is equal to or larger than 10 times the resistance of the second photoconductive switch at the moment that the second photoconductive switch is illuminated by the light beam.

In an embodiment, the photoconductive switch comprises low temperature grown GaAs, also denoted as LT-GaAs, as photoconductive material. However, alternative semiconductors than LT-GaAs can also be used as photoconductors. Dielectric materials and graphene are in principle possible alternatives.

According to a third aspect, the present invention provides an apparatus for inspecting a surface of a sample, wherein the apparatus comprises:

a charged particle generator for generating a charged particle beam,

a charged particle optical system for projecting and/or focusing the charged particle beam into the sample,

a stop comprising an aperture or slit, which stop is arranged in a trajectory of the charged particle beam from the charged particle generator towards the sample,

a device as described above or an embodiment thereof, wherein the deflection unit is arranged in or along the trajectory of the charged particle beam between the charged particle generator and the stop, and is arranged for deflecting the charged particle beam over the stop and across the aperture or slit, at least when said photoconductive switch is illuminated by a light beam, and

a light source system for generating a pulsed light beam which is projected onto the photoconductive switch of the device.

In use, the charged particle generator emits a beam of charged particles, for example an electron beam, which is projected and/or focused onto the surface of a target by a charged particle optical system. Along the trajectory of the charged particle beam a stop comprising a slit or aperture is arranged. Between the slit or aperture and the charged particle generator, the device comprising the deflection unit is arranged. When the deflection unit is switched off, and the charged particle beam is not deflected, the charged particle beam is transmitted through said slit or aperture, and the apparatus for inspecting a sample can be used without ultra fast pulses.

When the charged particle beam is deflected by the deflection unit, the stop which comprises said aperture or slit will intercept the beam. When the field in the deflector is changed, preferably reversed, the charged particle beam sweeps over the stop, from one side to the other side across the slit or aperture. During said sweep, the charged particle beam briefly passes through the slit or aperture forming a short pulse of charged particles which is projected and/or focused on the sample. Due to the photoconductive switch the voltage driving the deflection unit can be changed very fast yielding a fast sweep of the charged particle beam over the slit or aperture, and thus a short pulse of charged particles.

In an embodiment, the light source system comprises a pulsed laser system, preferably a pulsed laser system arranged for generating photon pulses of 10 ps or less. The pulsed laser is used for illuminating the photoconductive switch. In an embodiment, the apparatus comprises a beam splitter for splitting the pulsed light beam and directing a part of the pulsed light beam towards the sample for, in use, illuminating said sample.

In an embodiment, the charged particle optical system comprises a charged particle lens arranged between the charged particle generator and the deflection unit, wherein the deflection unit is arranged substantially at a crossover or focal point of the charged particle beam. By arranging the deflection at or near the crossover or focal point, the charged particle beam can be blanked faster. Due to the crossover or focus the electrodes for providing the deflection field in the deflector unit can be physically located close to each other for providing a high deflection field for a given voltage.

In an embodiment, the charged particle optical system further comprises a scanning deflector for scanning the charged particle beam over a surface of the sample, wherein the aperture or slit is substantially arranged in a pivot point of the scanning deflector. By arranging the scanning deflector such that the pivot point of the scanning deflector is at or near the aperture or slit, the pulsed charged particle beam can be scanned over the surface of the sample.

In an embodiment, the deflection unit is mounted onto a manipulator device for moving the deflection unit at least in a plane substantially perpendicular to an optical axis of the charged particle optical system. The manipulator can be used for accurate positioning of the deflection unit with respect to the trajectory of the charged particle beam.

In an embodiment, the manipulator is provided with an optical lens for focusing the pulsed light beam onto the photoconductive switch, preferably wherein the optical lens and the deflection unit are arranged on the manipulator at a fixed position with respect to each other.

In an embodiment, the apparatus comprises a camera for observing an area of the deflection unit comprising the photoconductive switch, preferably via the optical lens for focusing the pulsed light beam. The camera can be used for observing, in particular for aligning the light beam or laser beam onto the photoconductive switch.

According to a fourth aspect, the invention provides a method for inspecting a surface of a sample using an apparatus as described above, wherein said method comprises the steps of:

generating a charged particle beam using a charged particle generator;

projecting the charged particle beam from the charged particle generator, via the deflection unit, onto the stop,

illuminating the photoconductive switch by a light beam from the light source, which conductively connects the deflection unit to the electrical driving circuit to generating an electric field for deflecting said charged particle beam over the stop and across the aperture or slit,

wherein the charged particle beam is projected to and/or focused onto the sample when said charged particle beam at least partially passes through said aperture or slit during its manipulation over the stop.

According to a further aspect, the invention relates to a device for generating charged particle beam pulses or for modifying charged particle beam pulses, wherein the device comprises a buncher unit which is positioned in or along a trajectory of a charged particle beam, and wherein the buncher unit is arranged for generating an electric field for accelerating or decelerating charged particles of said charged particle beam, wherein the device comprises an electrical driving circuit for providing a voltage to the buncher unit, wherein the electrical driving circuit is electrically connected to the buncher unit via a photoconductive switch, wherein the photoconductive switch is arranged for:

substantially insulating the buncher unit from the electrical driving circuit, and for

conductively connecting the buncher unit to the electrical driving circuit when said photoconductive switch is illuminated by a light beam of an intensity larger than a predetermined intensity value.

The buncher unit according to this embodiment is arranged to provide an electrostatic field which, in use, is directed substantially parallel to the trajectory of the charged particle beam for accelerating or decelerating the charged particles. When synchronized to an incoming pulse of charged particles, the buncher unit is arranged to accelerate or decelerate the charged particles depending on the arrival time of the charged particle at the buncher unit, which can be used to bunch or compress a pulse of charged particles, in order to obtain a short or shortened pulse of charged particles. It is noted that the propagation direction of the charged particle beam is along said trajectory and is not substantially altered by said buncher unit.

In an embodiment, the electrodes are arranged one after the other along the trajectory of the charged particle beam. The electrodes are arranged in order to provide that the space between the first and second electrode extends substantially perpendicular to the trajectory of the charged particle beam, at least near said trajectory.

The various aspects and features described and shown with respect to the deflection unit, in particular the aspects and features described in the attached dependent claims may also suitably be applied to the buncher unit.

The various aspects and features described and shown in the specification can be applied, individually, wherever possible. These individual aspects, in particular the aspects and features described in the attached dependent claims, can be made subject of divisional patent applications.

### BRIEF DESCRIPTION OF THE DRAWINGS

The invention will be elucidated on the basis of an exemplary embodiment shown in the attached drawings, in which:

FIG. 1 shows a schematic view of an embodiment of the invention, comprising a deflection unit controlled by a photoconductive switch arranged in a scanning electron microscope;

FIG. 2A schematically shows a deflection unit integrated with a photoconductive switch on a chip, a view from a perspective along the electron-optical axis (top) and a view along the laser axis (bottom), according to the invention;

FIG. 2B shows a cross section view along the line IIB-IIB in FIG. 2A;

FIG. 3 schematically shows an example where the chip containing the deflection unit and photoconductive switch is mounted on a manipulator stick;

FIG. 4 shows a schematic of another example of a photoconductive switch and a deflection unit according to the invention;

FIG. 5 shows a schematic of another example of two photoconductive switches and a deflection unit according to the invention;

FIGS. 6A and 6B schematically show examples of the timing of the voltage as function of time from the electrical supply (solid line) and the voltage over the deflector (dotted line) and the laser pulses (circles); and

FIG. 7 schematically shows an example of a buncher.

### DETAILED DESCRIPTION OF THE INVENTION

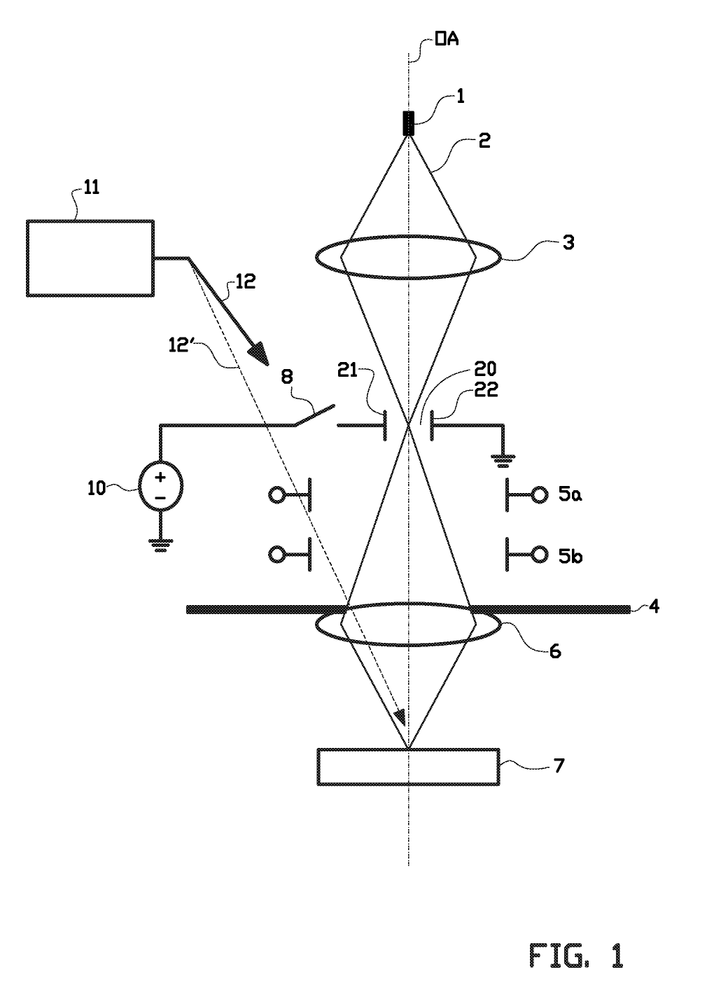

FIG. 1 schematically shows an apparatus for inspecting a surface of a sample 7, such as a Scanning Electron Microscope with a deflection unit 20 according to the invention. The apparatus may also be a transmission electron microscope or a scanning transmission electron microscope, for example.

The apparatus comprises a charged particle generator, in particular an electron source 1 with high brightness. The electron source 1 comprises for example a Schottky source or a cold field emitter, which is arranged for emitting a beam of electrons 2 along an electron-optical axis OA. In addition or alternatively the electron source 1 can also be a sharp metal tip where electrons are extracted using femtosecond optical pulses.

The apparatus further comprises a charged particle optical system for projecting and/or focusing the electron beam 2 into the sample 7. The charged particle optical system comprises a magnetic or electrostatic lens 3 or a combination of lenses to focus the electron beam 2 in an intermediate crossover. A subsequent objective lens 6 is arranged to focus the electron beam onto the surface of the sample 7. Between the intermediate crossover and the objective lens 6, a stop 4 is arranged, which stop comprises an aperture or slit. Such a stop is also referred to as a ‘diaphragm’. The stop 4 is arranged in a trajectory of the electron beam 2 from the electron source 1 towards the sample 7.

In addition, scanning deflectors 5a, 5b are provided for scanning the electron beam 2 over the surface of the sample 7. The scanning deflectors 5a, 5b in a Scanning Electron Microscope comprises scanning coils. The scanning deflectors 5a, 5b are arranged so that the pivot point of the scanning deflectors 5a, 5b is arranged substantially at the slit of aperture of the stop 4.

At or near the intermediate crossover, a deflection unit 20 is arranged in or along the trajectory of the electron beam 2. The deflection unit 20 is arranged for deflecting the electron beam 2 over the stop 4 and across the aperture or slit. When the electron beam 2 is deflected by the deflection unit 20, the electron beam 2 is intercepted by the stop 4 and is blocked from reaching the sample 7. The deflection unit 20 in combination with the stop 4 with the slit of aperture forms a beam blanker.

The deflector unit 20 is preferably located in the crossover, because the electron beam 2 can be blanked faster. In that configuration the electrodes 21, 22 of the deflection unit 20 can be physically located close to each other and high deflection fields for a given voltage can be created resulting in a blanking angle α_{b} equal to:

α_{b}=V_{b}L/2Φd

where L is the length of the deflector electrodes 21, 22 along the electron-optical axis OA, Φ is acceleration voltage of the electron beam 2, where V_{b} is the blanking voltage difference over the electrodes 21, 22 and d is the distance between the electrodes 21, 22. The distance d between the electrodes 21, 22 is for example about 1 μm. Suitable values for this example are a blanking voltage of 3 V for a deflection unit with 6 μm long deflector electrodes 21, 22 at a beam energy of 30 keV. A voltage sweep of 20 V in 100 fs results in an electron pulse length of 30 fs.

An electrostatic deflector not only deflects the electron beam 2 but also displaces it. The displacement depends on the direction of the deflection field. This displacement provides a potential problem for a beam blanker driven with oscillating fields as described in U.S. Pat. No. 8,569,712. For a 20 GHz, 100 μm long blanker as typical in a deflector according to U.S. Pat. No. 8,569,712, the total displacement is about 40 nm in total. For a deflection unit according to current invention with a frequency of roughly about 2.5 THz and a length L of the electrodes 21, 22 of approximately 6 μm, it was found that the total displacement is limited to approximately 1 nm.

According to the invention such a fast voltage sweep is achieved by integration of the deflection unit 20 with a photoconductive switch 8 which is arranged in between the electrical driving circuit 10 and at least one of the deflection electrodes 21. As indicated in FIG. 1, the other one of the deflection electrodes 22 can be connected to earth potential.

The apparatus of the invention is further provided with a light source system, for example a pulsed laser system 11 for generating a pulsed light beam 12 which is projected onto the photoconductive switch 8 of the deflection unit 20. In addition, the light source system may also be arranged to split off a part of the pulsed light beam 12′, which is used to illuminate the sample 7, for example to perform pump-probe type of experiments on the sample 7.

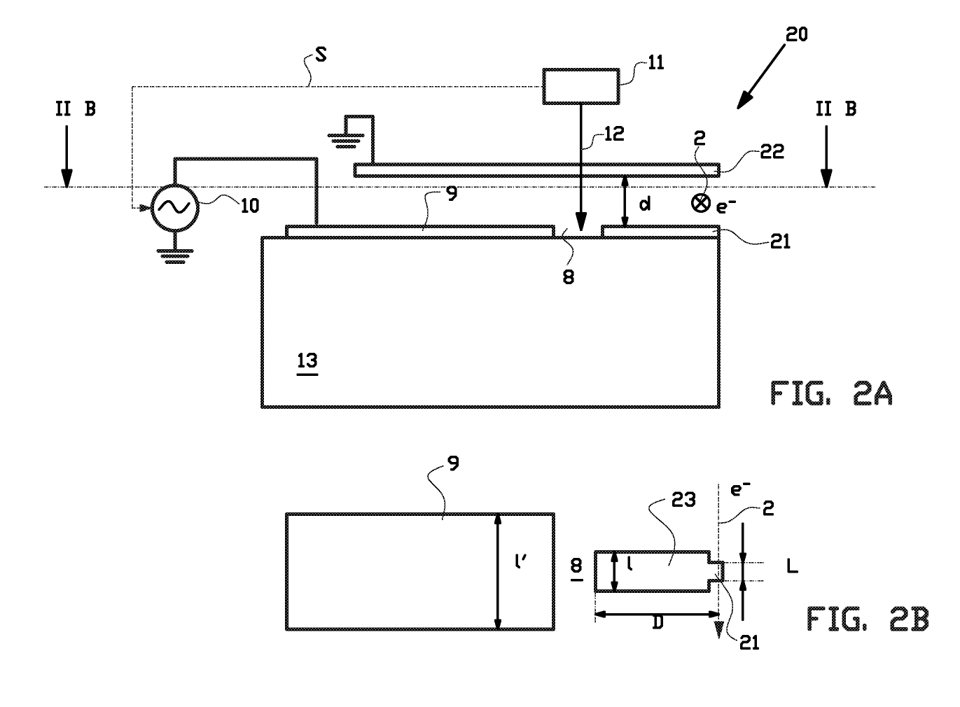

As shown in more detail in the example of FIG. 2A, the photoconductive switch 8 is located close to the deflection electrodes 21, 22 of the deflection unit 20. Preferably, the photoconductive switch 8 and the deflection unit 20 are integrated on one single chip 13. It has been established that good results, that is fast voltage sweeps, can be obtained when the distance D between the photoconductive switch 8 and the deflection unit 20 is limited to several hundreds of micrometers, and the width l of the conducting strip 23 between the photoconductive switch 8 and the deflection electrodes 21, 22 is approximately 10 micron and the electrode 22, 21 separation d is approximately 1 micron.

In the example as shown in FIG. 2B, the width l′ of the conducting strip of the supply side 9 is larger than the width l of the conducting strip 23 between the photoconductive switch 8 and the deflection electrodes 21, 22. In this embodiment, the capacitance per meter on the supply side 9 is higher compared to the capacitance per meter on the side of the deflection unit 20. In that case only a relatively short part of the electrical supply line has to be used to charge the deflection plates 21. Using for example a micro-strip line for connecting the photoconductive switch 8 to the electrical supply 10, having a width l′ of 30 μm and a separation d of 1 μm between the lines, a capacitance of about 2.7 10⁻¹⁰ F/m is obtained. The capacitance of the deflection electrodes 21, 22 plus connection 23 to the switch 8 is typically about 6 fF. This means that approximately the first 225 μm of the line 9 contains enough charges to discharge the 6 fF and still keep about 90% of its initial voltage.

Another reason to use a relatively high capacitance per unit length of the supply line 9 connecting the photoconductive switch 8 to the supply 10 is to increase the amplitude of the injected signal. If the deflector electrode 21 is on a voltage −Vbias and the supply delivers a voltage +Vbias, and a laser pulse 11 illuminates the photoconductive switch 8, a voltage step (with a rise time set approximately by the laser pulse length) is injected in the deflector electrode. In a working example, the impedance of the deflector electrode 21 is typically about 30Ω), and the impedance of the line 9 connecting the photoconductive switch 8 to the supply 10 is about 10Ω. The resistance of the photoconductive switch 8 after illumination is estimated to be 20Ω. The injected voltage step will substantially double at the end of the deflector 21 due to reflection. For this reason it is preferred to have the electron-optical axis OA at this point.

As mentioned before the bias voltage generated by an electrical circuit 10 applied on the photoconductive switch 8 is modulated at a rate half the repetition rate of the pulsed laser system 11. Preferably the electrical circuit 10 and the pulsed laser system 11 are synchronized by an electrical or optical synchronization coupling S.

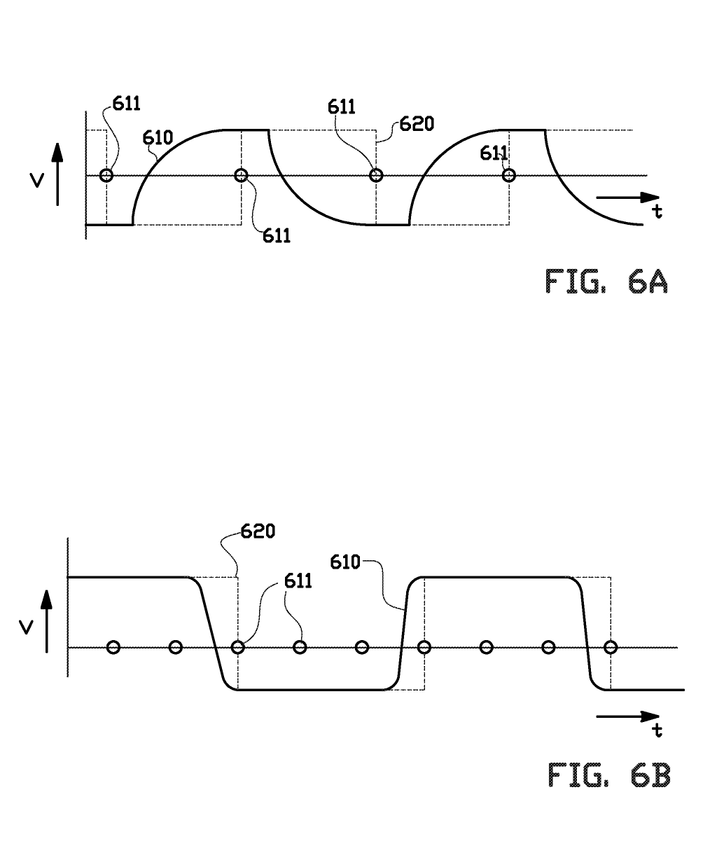

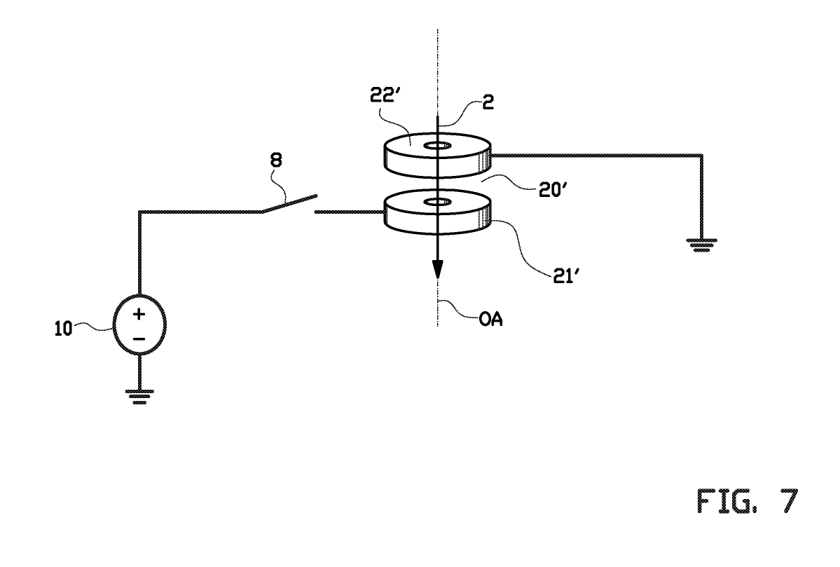

FIG. 6A shows an example of the voltage 610 as function of time from the electrical circuit 10 (solid line), at each laser pulse 611 (circles) the voltage 620 over the deflection electrodes 21, 22 (dotted line) makes a zero crossing. The laser pulse 611 brings the photoconductive switch 8 in a conductive state and the deflection electrode 21 takes over the voltage 610 on the supply line 9 of the photoconductive switch 8. It is preferred that the voltage 610 over the photoconductive switch 8 can be changed without affecting the voltage 620 on the deflection electrode 21 when the photoconductive switch 8 is in the substantially insulating state or off state. The off state is defined as the dark state having a significantly reduced conductivity due to recombination of charge carriers. Preferably, the photoconductor switch 8 has a high value of the dark resistance and therefore a relatively short recombination time. In a preferred embodiment, were the photoconductor is LT-GaAs, the off resistance will be equal to the dark resistance of the photoconductive switch, order of magnitude up to 5 10¹¹Ω. Another reason for the preference of LT-GaAs as a photoconductor is the low resistance in the photoconductive state.

More general, the voltage 610 generated by an electrical circuit 10 applied on the photoconductive switch 8 is modulated at 1/(2n) times the repetition rate of the pulsed laser system 11. For some experiments it can be advantageous to use a low repetition rate for the electron pulses, when compared to the repetition rate of the pulsed laser system 11. For example, such an experiment comprises the measurement of a decay time longer than the time between to laser pulses. In another example, the light from the laser 11 is converted to different wavelengths and lower repetition rates, and used to illuminate the sample. The pulses directly from the laser 11 have in that case a too high repetition rate, and it is necessary to modulate the deflection module at a lower frequency than the repetition rate of the laser, in order too still have synchronized light and electron pulses at the sample.

As clearly indicated in FIG. 6, the voltage 620 on the deflection unit is not affected when the photoconductive switch 8 is substantially insulating. Thus, after the photoconductive switch 8 is illuminated 611 by the light beam 11, the voltage 610 of the electrical driving circuit is transmitted to the deflection unit, the illumination of the photoconductive switch 8 is stopped and the photoconductive switch returns to the substantially insulating state, the voltage 620 on the deflection unit substantially does not change and is substantially held at the voltage 610 of the electrical driving circuit which was transmitted to the deflection unit during the illumination 611 of the photoconductive switch 8. The voltage 620 on the deflection unit is substantially unaffected and constant until the photoconductive switch 8 is illuminated 611 again. Because the voltage 620 on the deflection unit between successive illuminations 611 remains substantially constant, the charged particle beam substantially remains at the same position, at particular at the same side next to the aperture or slit of the stop. A next deflection of the charged particle beam to sweep over the stop and from one side to the other side across the aperture or slit will occur when the voltage 610 of the electrical driving circuit has changed and the photoconductive switch is illuminated 611 to transmit the changed voltage of the driving circuit to the deflection unit.

FIG. 6B shows an example in which the electrical circuit provides a voltage 610 having a frequency which is ⅙ times the repetition rate of the pulsed laser system. The laser pulses 611 brings the photoconductive switch 8 in a conductive state and the deflection electrode 21 takes over the voltage 610 on the supply line 9 of the photoconductive switch 8. Only when the voltage 610 as provided by the electrical circuit has changed, in particular has reversed, between two subsequent laser pulses 611, the voltage 620 over the deflection electrodes 21, 22 (dotted line) makes a zero crossing and the electron beam sweeps over and across the aperture 4 to generate an electron pulse.

When the laser pulse illuminating the photoconductive switch 8 has an energy in the order of 50 pJ, creating about 10⁸ electron-hole pairs in a 10 by 10 micron photoconductive switch, the resulting resistance of the photoconductive switch is approximately 20Ω. About 10⁶ of these carriers are used to (de)charge the deflection electrode 21. The photoconductive switch cannot deliver more charges than are created by the laser pulse, neglecting dark resistivity of the photoconductor. Thus the resistance of the photoconductor in its photoconductive state can be set by the amount of photons in the laser pulse, causing a decrease in the rise time of the deflection field. According to the invention this method can be used to increase the pulse length and thus to increase the amount of electrons on the sample. Instead of changing the amount of photons, it also possible to adjust the amplitude of the voltage from the supply 10.

In the same way the spatial resolution of the electron microscope can be improved, provided that longer electron pulses are acceptable. The spatial resolution can be improved by limiting the opening angle of the electron beam 2 at a point between the electron source 1 and the deflector unit 20. Normally this would decrease the electron pulse length and reduce the current on the sample. However with the current invention, the laser pulse energy used to illuminate the photoconductive switch 8 can be reduced to compensate for the reduction in electron pulse length.

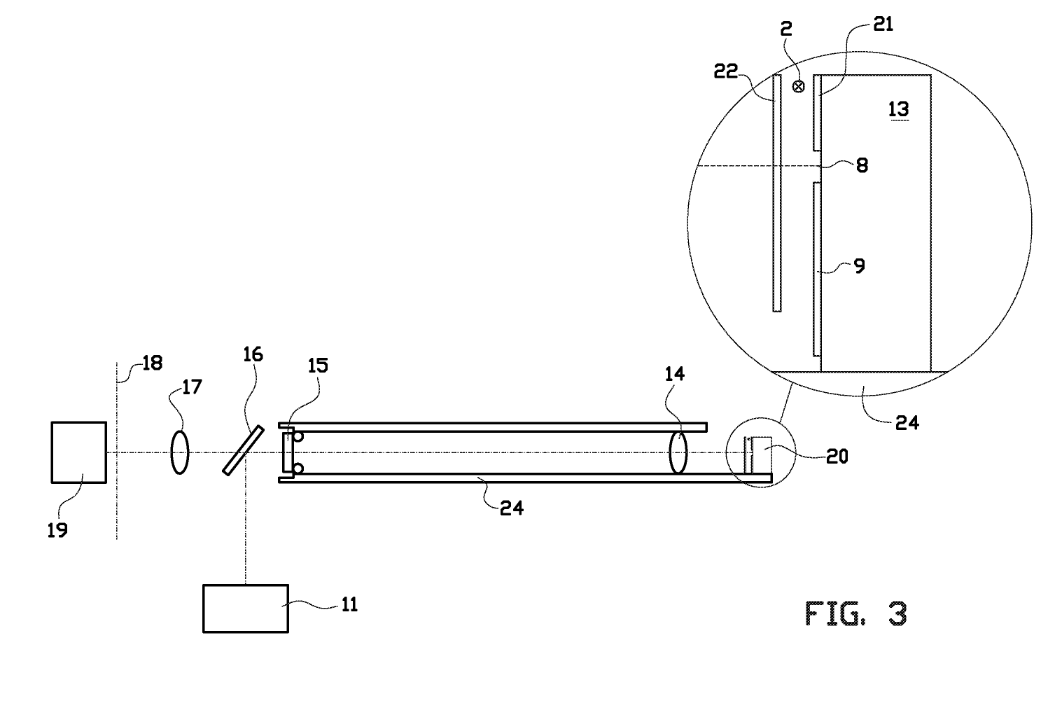

In the example shown in FIG. 3, an optical lens 14 is used to focus the laser pulse from the pulsed laser 11 on the 10 by 10 μm photoconductive switch 8. The lens 14 and chip 13 containing the deflection electrodes 21, 22 and photoconductive switch 8 are mounted on a manipulator device, in particular comprising a stick 24. The stick 24 is hollow along the optical axis to allow the laser pulse to propagate freely through the stick 24 towards the lens 14. The laser beam is coupled into the stick 24 via a transparent window 15 which ensures a vacuum tight system. A half transparent mirror or dichroic mirror 16, outside the vacuum is used to couple the laser pulse into the stick 24. The half transparent mirror or dichroic mirror 16 is located between the vacuum window and a tube lens 17. The tube lens creates an image of the chip 13 in the image plane 18, where a camera 19 is placed. The camera is used to align the laser beam on the photoconductive switch 8. In order to get an image of the chip 13 it can be necessary to couple in an additional light source via the half transparent or dichroic mirror 16. The stick 24 can be mechanically moved in the plane perpendicular to the electron-optical axis OA to align the chip 13 containing the deflection electrodes 21, 22 with respect to the electron optical axis OA along which in used travels the electron beam 2.

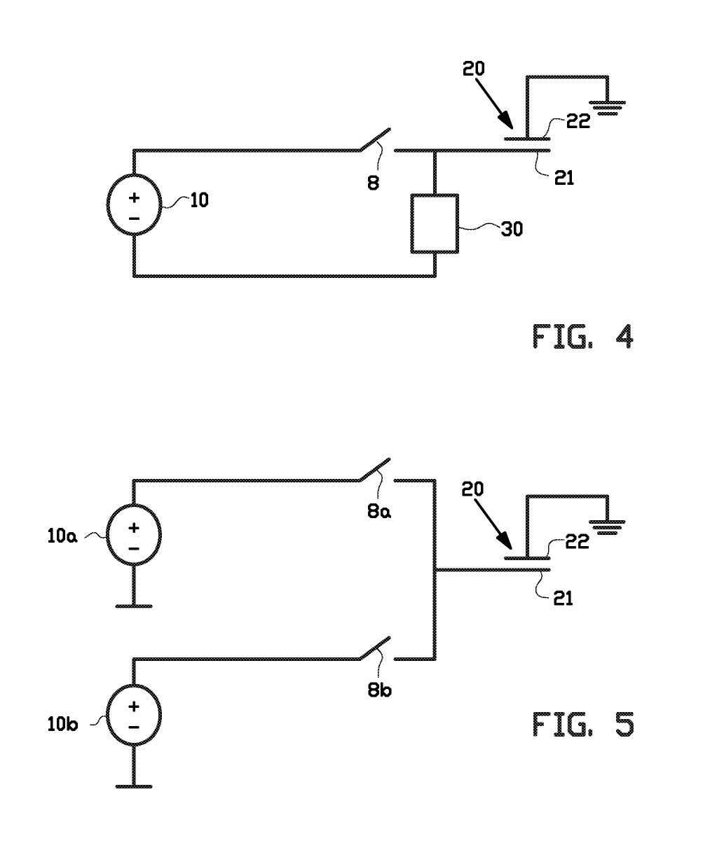

In another example as shown in FIG. 4, the photoconductive switch 8 is connected to a constant voltage from an electrical supply 10. The deflector electrode 21 is also connected to the supply 10 via a resistor 30 with a resistance substantially higher than the on resistance of the photoconductive switch 8 and substantially lower than the dark resistance of the photoconductive switch 8. In this example, the electron beam will sweep fast over the aperture in case the pulsed laser illuminates the photoconductive switch 8. However when the photoconductor goes back to its dark state, the beam will make a second slow sweep over the aperture, resulting in a longer second electron pulse. A pulse picker in the form of a second slower deflector, which deflects in a direction perpendicular to deflector unit 20 is preferably used in this example to move the electron beam away from the aperture during the second sweep so that the electron beam does not move across the aperture during the second sweep in order to block the second pulse. An advantage of this embodiment is, that the voltage of the electrical supply 10 can be substantially constant and does not need to be modulated.

In another example as shown in FIG. 5, two photoconductive switches 8a and 8b are connected to the deflection electrode 21 of the deflection unit 20. The two photoconductive switches 8a, 8b are biased with different voltages from the power sources 10a and 10b. In use, the switches 8a, 8b are alternately illuminated by a pulsed laser. For example, switch 8a is illuminated with even laser pulses and switch 8b is illuminated with odd laser pulses. The even laser pulse charges the deflection electrode 21 to the voltage delivered by the first electrical supply 10a. A subsequent odd pulse will charge the deflection electrode 21 to a voltage delivered by the second electrical supply 10b via photoconductive switch 8b. In this way the voltage on the deflector plate 21 will make a sweep in picosecond or femtosecond timescale from the voltage delivered by the first power source 10a to the voltage delivered by the second power source 10b, or the other way around when an even pulse illuminates photoconductive switch 8a. In this example it is preferred that the resistance of the photoconductive switch 8a, 8b is about an order of magnitude higher at the moment a subsequent laser pulse illuminates the other photoconductive switch 8b, 8a. An advantage of this embodiment is, that the voltages of the electrical supplies 10a, 10b can be substantially constant and do not need to be modulated.

It is mentioned that the invention presented here can also be used to bunch or compress an electron pulse. FIG. 7 schematically shows an example of such a buncher. In this example the first 21′ and second 22′ electrodes are provided with through openings which are arranged to allow the passing of the charged particle beam 2. The through openings are aligned with the optical axis OA, and are arranged one after the other along the trajectory of the charged particle beam. As shown in FIG. 7, the electrodes 21′, 22′ are arranged in order to provide that the space 20′ between the first 21′ and second 22′ electrode extends substantially perpendicular to the optical axis OA, at least near said trajectory. In use, the electrodes provide an electric field which is directed substantially parallel to the electron-optical axis OA.

When it is synchronized to an incoming femtosecond electron pulse, electrons are accelerated or decelerated by the electric field between the first 21′ and second 22′ electrode, depending on the arrival time of the electrons in the buncher, the voltage provided by the electrical driving circuit 10, and the state of the photoconductive switch 8. For example, the electrons at the leading part of the electron pulse can be decelerated and/or the electrons at the trailing part of the electron pulse can be accelerated in order to compress the electron pulse. Hence the electron pulse at the sample can be shorter than the pulse entering the buncher. It is noted that the propagation direction of the charged particle beam 2 is not substantially altered and remains in the direction of the sample. Such a buncher can also be positioned before or after the deflection unit described above.

It is to be understood that the above description is included to illustrate the operation of the preferred embodiments and is not meant to limit the scope of the invention. From the above discussion, many variations will be apparent to one skilled in the art that would yet be encompassed by the spirit and scope of the present invention.

In summary, the invention relates to a device for generating charged particle beam pulses, an apparatus for inspecting a surface of a sample wherein said apparatus comprises such a device, and a method for inspecting a surface of a sample using such an apparatus. The device comprises a deflection or buncher unit which is arranged for positioning in or along a trajectory of a charged particle beam. The deflection unit is arranged for generating an electric field for deflecting said charged particle beam. The buncher unit is arranged for generating an electric field for decelerating and/or accelerating electrons of said charged particle beam. The device comprises an electrical driving circuit for providing a voltage to the deflection unit or buncher unit. The electrical driving circuit is connected to the deflection unit or buncher unit via a photoconductive switch, wherein the photoconductive switch is arranged for:

substantially insulating the deflection or buncher unit from the electrical driving circuit, and for

conductively connecting the deflection or buncher unit to the electrical driving circuit only when said photoconductive switch is illuminated by a light beam.

1. A device for, in combination with a stop comprising an aperture or slit, generating charged particle beam pulses, wherein the device comprises a deflection unit which is arranged for positioning in or along a trajectory of a charged particle beam, and wherein the deflection unit is arranged for generating an electric field for deflecting said charged particle beam over said stop and across the aperture or slit, wherein the device comprises an electrical driving circuit for providing a voltage to the deflection unit,
wherein the electrical driving circuit is electrically connected to the deflection unit via a photoconductive switch, wherein the photoconductive switch is arranged for:
conductively connecting the deflection unit to the electrical driving circuit when said photoconductive switch is illuminated by a light beam of an intensity larger than a predetermined intensity value, for transmitting the voltage of the electrical driving circuit to the deflection unit, and
substantially insulating the deflection unit from the electrical driving circuit when the photoconductive switch is not illuminated by a light beam, wherein the voltage over the photoconductive switch can be changed without affecting the voltage on the deflection electrode when the photoconductive switch is substantially insulating.

2. The device according to claim 1, wherein the electrical driving circuit is arranged for generating an alternating voltage, and for providing said alternating voltage to the photoconductive switch at a side thereof facing away from the deflection unit.

3. The device according to claim 2, wherein the electrical driving circuit is arranged for synchronizing the alternating voltage to a repetition rate of a pulsed laser system which is used for illuminating the photoconductive switch.

4. The device according to claim 2, wherein the alternating voltage is modulated with 1/(2n) times the repetition rate of a pulsed laser system which is used for illuminating the photoconductive switch, wherein n is an integer value larger than 0.

5. A device for, in combination with a stop comprising an aperture or slit, generating charged particle beam pulses, wherein the device comprises a deflection unit which is arranged for positioning in or along a trajectory of a charged particle beam, and wherein the deflection unit is arranged for generating an electric field for deflecting said charged particle beam over said stop and across the aperture or slit, wherein the device comprises an electrical driving circuit for providing a voltage to the deflection unit, wherein the electrical driving circuit is electrically connected to the deflection unit via a photoconductive switch, wherein the photoconductive switch is arranged for:
substantially insulating the deflection unit from the electrical driving circuit, and for
conductively connecting the deflection unit to the electrical driving circuit when said photoconductive switch is illuminated by a light beam of an intensity larger than a predetermined intensity value, wherein the deflection unit is also connected to the electrical driving circuit or to ground potential via a resistor, wherein the resistor has a resistance substantially higher than a resistance of the photoconductive switch when said photoconductive switch is illuminated by a light beam.

6. The device according to claim 5, wherein the driving circuit comprises a power supply, wherein said power supply, said photoconductive switch and said resistor are arranged in series to provide an electric circuit, and wherein the deflection unit is connected to said electric circuit in between said photoconductive switch and said resistor.

7. The device according to claim 6, wherein the power supply is arranged to provide a substantially constant voltage.

8. The device according to claim 1, wherein the deflection unit comprises a first and a second electrode, which are arranged at a distance from each other, and wherein at least one of said first and second electrode is connected to the electrical driving circuit.

9. The device according to claim 8, wherein the photoconductive switch is directly connected to the first electrode, preferably wherein the photoconductive switch is arranged directly adjacent to the first electrode.

10. The device according to claim 1, wherein the deflection unit and the photoconductive switch are arranged and/or integrated on one single chip.

11. The device according to claim 1, wherein the electrodes are arranged at substantially opposite sides of the trajectory of the charged particle beam, preferably wherein the electrodes are arranged in order to provide a passage for the charged particle beam between the first and second electrode.

12. The device according to claim 11, wherein the deflection unit is a first deflection unit, and wherein the device comprises a second deflector which is arranged for positioning in or along a trajectory of a charged particle beam, and wherein the second deflector is arranged for generating a second electric field in a direction substantially perpendicular to the electric field of the first deflection unit.

13. The device according to claim 1, wherein the photoconductive switch is a first photoconductive switch, wherein the electrical driving circuit comprises a first power supply which is connected to the deflection unit via the first photoconductive switch, and wherein the electrical driving circuit comprises a second power supply which is connected to the deflection unit via a second photoconductive switch.

14. The device according to claim 13, wherein the first and second photoconductive switches are arranged for alternately illumination by the light beam.

15. The device according to claim 13, wherein a resistance of the first photoconductive switch is equal to or larger than ten times the resistance of the second photoconductive switch at the moment that the second photoconductive switch is illuminated by the light beam.

16. The device according to claim 1, wherein the photoconductive switch comprises LT-GaAs as photoconductive material.

17. An apparatus for inspecting a surface of a sample, wherein the apparatus comprises:
a charged particle generator for generating a charged particle beam,
a charged particle optical system for projecting and/or focusing the charged particle beam into the sample,
a stop comprising an aperture or slit, which stop is arranged in a trajectory of the charged particle beam from the charged particle generator towards the sample,
a device according to claim 1, wherein the deflection unit is arranged in or along the trajectory of the charged particle beam between the charged particle generator and the stop, and is arranged for deflecting the charged particle beam over the stop and across the aperture or slit, at least when said photoconductive switch is illuminated by a light beam, and
a light source system for generating a pulsed light beam which is projected onto the photoconductive switch of the device.

18. The apparatus according to claim 17, wherein the light source system comprises a pulsed laser system, preferably a pulsed laser system arranged for generating photon pulses of 10 ps or less.

19. The apparatus according to claim 17, wherein the charged particle optical system comprises a charged particle lens arranged between the charged particle generator and the deflection unit, wherein the deflection unit is arranged substantially at a crossover or focal point of the charged particle beam.

20. The apparatus according to claim 17, wherein the charged particle optical system comprises a scanning deflector for scanning the charged particle beam over a surface of the sample, wherein the aperture or slit is substantially arranged in a pivot point of the scanning deflector.

21. The apparatus according to claim 17, wherein the deflection unit is mounted onto a manipulator device for moving the deflection unit in a plane substantially perpendicular to an optical axis of the charged particle optical system.

22. The apparatus according to claim 21, wherein the manipulator is provided with an optical lens for focusing the pulsed light beam onto the photoconductive switch, preferably wherein the optical lens and the deflection unit are arranged on the manipulator at a fixed position with respect to each other.

23. The apparatus according to claim 21, wherein the apparatus comprises a camera for observing an area of the deflection unit comprising the photoconductive switch, preferably via the optical lens for focusing the pulsed light beam.

24. The apparatus according to claim 17, wherein the apparatus comprises a beam splitter for splitting the pulsed light beam and directing a part of the pulsed light beam towards the sample for, in use, illuminating said sample.

25. A method for inspecting a surface of a sample using an apparatus according to claim 17, wherein said method comprises the steps of:
generating a charged particle beam using a charged particle generator;
projecting the charged particle beam from the charged particle generator, via the deflection unit, onto the stop,
illuminating the photoconductive switch by a light beam from the light source, which conductively connects the deflection unit to the electrical driving circuit to generating an electric field for deflecting said charged particle beam over the stop and across the aperture or slit,
wherein the charged particle beam is projected to and/or focused onto the sample when said charged particle beam at least partially passes through said aperture or slit during its deflection over the stop.

26. The device according to claim 5, wherein the deflection unit and the photoconductive switch are arranged and/or integrated on one single chip.

27. The device according to claim 5, wherein the electrodes are arranged at substantially opposite sides of the trajectory of the charged particle beam, preferably wherein the electrodes are arranged in order to provide a passage for the charged particle beam between the first and second electrode.

28. The device according to claim 26, wherein the deflection unit is a first deflection unit, and wherein the device comprises a second deflector which is arranged for positioning in or along a trajectory of a charged particle beam, and wherein the second deflector is arranged for generating a second electric field in a direction substantially perpendicular to the electric field of the first deflection unit.

29. The device according to claim 5, wherein the photoconductive switch is a first photoconductive switch, wherein the electrical driving circuit comprises a first power supply which is connected to the deflection unit via the first photoconductive switch, and wherein the electrical driving circuit comprises a second power supply which is connected to the deflection unit via a second photoconductive switch.

30. The device according to claim 28, wherein the first and second photoconductive switches are arranged for alternately illumination by the light beam.

31. The device according to claim 28, wherein a resistance of the first photoconductive switch is equal to or larger than ten times the resistance of the second photoconductive switch at the moment that the second photoconductive switch is illuminated by the light beam.

32. The device according to claim 5, wherein the photoconductive switch comprises LT-GaAs as photoconductive material.

33. An apparatus for inspecting a surface of a sample, wherein the apparatus comprises:
a charged particle generator for generating a charged particle beam,
a charged particle optical system for projecting and/or focusing the charged particle beam into the sample,
a stop comprising an aperture or slit, which stop is arranged in a trajectory of the charged particle beam from the charged particle generator towards the sample,
a device according to claim 5, wherein the deflection unit is arranged in or along the trajectory of the charged particle beam between the charged particle generator and the stop, and is arranged for deflecting the charged particle beam over the stop and across the aperture or slit, at least when said photoconductive switch is illuminated by a light beam, and
a light source system for generating a pulsed light beam which is projected onto the photoconductive switch of the device.

34. The apparatus according to claim 32, wherein the light source system comprises a pulsed laser system, preferably a pulsed laser system arranged for generating photon pulses of 10 ps or less.

35. The apparatus according to claim 32, wherein the charged particle optical system comprises a charged particle lens arranged between the charged particle generator and the deflection unit, wherein the deflection unit is arranged substantially at a crossover or focal point of the charged particle beam.

36. The apparatus according to claim 32, wherein the charged particle optical system comprises a scanning deflector for scanning the charged particle beam over a surface of the sample, wherein the aperture or slit is substantially arranged in a pivot point of the scanning deflector.

37. The apparatus according to claim 32, wherein the deflection unit is mounted onto a manipulator device for moving the deflection unit in a plane substantially perpendicular to an optical axis of the charged particle optical system.

38. The apparatus according to claim 36, wherein the manipulator is provided with an optical lens for focusing the pulsed light beam onto the photoconductive switch, preferably wherein the optical lens and the deflection unit are arranged on the manipulator at a fixed position with respect to each other.

39. The apparatus according to claim 36, wherein the apparatus comprises a camera for observing an area of the deflection unit comprising the photoconductive switch, preferably via the optical lens for focusing the pulsed light beam.

40. The apparatus according to claim 36, wherein the apparatus comprises a beam splitter for splitting the pulsed light beam and directing a part of the pulsed light beam towards the sample for, in use, illuminating said sample.

41. A method for inspecting a surface of a sample using an apparatus according to claim 32, wherein said method comprises the steps of:
generating a charged particle beam using a charged particle generator;
projecting the charged particle beam from the charged particle generator, via the deflection unit, onto the stop,
illuminating the photoconductive switch by a light beam from the light source, which conductively connects the deflection unit to the electrical driving circuit to generating an electric field for deflecting said charged particle beam over the stop and across the aperture or slit,
wherein the charged particle beam is projected to and/or focused onto the sample when said charged particle beam at least partially passes through said aperture or slit during its deflection over the stop.
